(19) United States
(12) Patent Application Publication
(10) Pub. No.: US 2022/0252655 A1
(43) Pub. Date: Aug. 11, 2022

(54) POWER LINE MONITORING

(71) Applicant: ST Engineering Telematics Wireless Ltd., Holon (IL)

(72) Inventors: Roman Sternberg, Magshimim (IL); Eddy Kafry, Hod Hasharon (IL); Moshe Nissim, Ness Ziona (IL); Yoav Elizur, Petach Tikva (IL)

(21) Appl. No.: 17/666,615

(22) Filed: Feb. 8, 2022

Related U.S. Application Data
(60) Provisional application No. 63/146,733, filed on Feb. 8, 2021.

(51) Int. Cl. G01R 31/08; G01S 19/01; H05B 47/19

(52) U.S. Cl. CPC G01R 31/085; F21S 8/085; H05B 47/19; G01S 19/01

(57) ABSTRACT

A street light control system includes a plurality of street lights connected to an electrical distribution grid of power lines, a communication network, and a street light central control server. Each street light includes a luminaire and a control unit with an electricity meter. In addition, the system includes an activator and a power line analyzer. The activator identifies a set of luminaires in a vicinity of a power line problem and instructs them to switch from a street light mode to a power line monitoring mode in which operating parameters of their electricity meters are changed so as to act as power line monitors. The power line analyzer receives data via the communication network from the power line monitors and to create a power line behavior picture.

### CROSS REFERENCE TO RELATED APPLICATIONS

This application claims priority from U.S. provisional patent application 63/146,733, filed Feb. 8, 2021, which is incorporated herein by reference.

### FIELD OF THE INVENTION

The present invention relates to power lines generally and to monitoring their operation in particular.

### BACKGROUND OF THE INVENTION

Power companies provide power across long distances on high tension wires. These wires deliver power to a city while the power lines delivering power to homes within the city are lower tension wires. The power lines form a grid within a city and occasionally underperform, at which point, the power company has to identify the location and the type of anomaly on the power lines. This can be difficult.

Power companies employ a myriad of means across the grid and in different locations to compensate and improve supplied power quality on a local/regional basis. They also monitor supplied power quality. However, consumers and customers pay higher than necessary electricity bills if power quality is not adequate. Furthermore, power lines which are not compliant with required quality standards may damage electrical and electronic equipment.

### SUMMARY OF THE PRESENT INVENTION

There is therefore provided, in accordance with a preferred embodiment of the present invention, a street light control system which includes a plurality of street lights connected to an electrical distribution grid of power lines, a communication network, and a street light central control server. Each street light includes a luminaire and a control unit comprising an electricity meter. In addition, the system includes an activator and a power line analyzer. The activator identifies a set of luminaires in a vicinity of a power line problem and instructs them to switch from a street light mode to a power line monitoring mode in which operating parameters of their electricity meters are changed so as to act as power line monitors. The power line analyzer receives data via the communication network from said power line monitors and creates a power line behavior picture.

Moreover, in accordance with a preferred embodiment of the present invention, the power line behavior picture is a synchronized snap shot of power distribution in the vicinity of the power line problem.

Further, in accordance with a preferred embodiment of the present invention, the power line behavior picture is a measured picture of a portion of the electrical distribution grid.

Still further, in accordance with a preferred embodiment of the present invention, the operating parameters are changed from monitoring, during the street light mode, an average voltage to measuring, during the power line monitoring mode, at least extreme voltage and extreme current values over a defined period of time.

Moreover, in accordance with a preferred embodiment of the present invention, a control unit includes a unit to determine the average voltage and/or current of its street light, during the street light mode, from voltages and/or currents sampled at a high rate and wherein the high rate of sampling is used during the power line monitoring mode for measuring at least the extreme voltage and the extreme current values.

Further, in accordance with a preferred embodiment of the present invention, each control unit includes a synchronized clock, synchronized at least to clocks in other control units. The data is time-stamped by the synchronized clock.

Still further, in accordance with a preferred embodiment of the present invention, the synchronized clock receives a synchronization clock signal from one of the communication network, an astronomical clock, or a time-stamp portion of a GPS (global positioning system) unit.

Moreover, in accordance with a preferred embodiment of the present invention, the operating parameters are length of time for sampling and type of measurement.

Further, in accordance with a preferred embodiment of the present invention, the activator is implemented in the street light central control server or the control unit.

There is also provided, in accordance with a preferred embodiment of the present invention, a method for providing a power line behavior picture. The method includes having a plurality of street lights connected to an electrical distribution grid of power lines, a communication network, and a street light central control server, each street light comprising a luminaire and a control unit comprising an electricity meter, identifying a set of luminaires in a vicinity of a power line problem, instructing the identified luminaires to switch from a street light mode to a power line monitoring mode in which operating parameters of their electricity meters are changed so as to act as power line monitors, receiving data via the communication network from the power line monitors, and creating the power line behavior picture from the data.

Further, in accordance with a preferred embodiment of the present invention, the power line behavior picture is a synchronized snap shot of power distribution in the vicinity.

Still further, in accordance with a preferred embodiment of the present invention, the power line behavior picture is a measured picture of a portion of an electrical distribution grid.

Moreover, in accordance with a preferred embodiment of the present invention, the method includes changing the operating parameters from monitoring, during the street light mode, an average voltage to measuring, during the power line monitoring mode, at least extreme voltage and extreme current values over a defined period of time.

Further, in accordance with a preferred embodiment of the present invention, the method includes determining the average voltage and/or current of each identified luminaire, during the street light mode, from voltages and/or currents sampled at a high rate, and using the high rate of sampling during the power line monitoring mode for measuring at least the extreme voltage and the extreme current values.

Still further, in accordance with a preferred embodiment of the present invention, the method includes time-stamping the data by a synchronized clock forming part of each control unit.

Moreover, in accordance with a preferred embodiment of the present invention, the synchronized clock is a synchronization clock signal from the communication network, an astronomical clock, a system clock forming part of a microcontroller or a time-stamp portion of a GPS unit.

Further, in accordance with a preferred embodiment of the present invention, the operating parameters are length of time for sampling and type of measurement.

Finally, in accordance with a preferred embodiment of the present invention, the identifying and instructing are provided by the street light central control server or the control unit.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1A is a schematic illustration of a prior art street with multiple street lights;

FIG. 1B is a schematic illustration of an exemplary street light control unit;

FIG. 2, is a schematic illustration of a street light, power line monitoring (SLPLM) system, constructed and operative in accordance with a preferred embodiment of the present invention;

FIGS. 3A and 3B are flow chart illustrations of a background process and a foreground process, respectively, of the operation of a microcontroller in street light mode;

FIG. 3C is a flow chart illustration of a server process interacting with a control unit in street light mode;

FIGS. 4A-1 and 4A-2 form a flow chart illustration of a background process of the operation of the microcontroller during a power line monitoring mode;

FIG. 4B is a flow chart illustration of a server process interacting with a control unit during the power line monitoring mode; and

FIG. 5 is an illustration of an exemplary power line behavior picture.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Applicant has realized that power lines deliver power not only to homes and businesses but also to street lighting, which is one of the most essential services provided by municipalities and the lighting's electricity bill is one of their major expenses. While replacing older luminaires with LED luminaires can deliver reductions of up to 50% in energy usage, smart controls, including proactive maintenance, can slash annual operating costs even further.

The power line that feeds the street lights usually also provides electricity to other industrial, commercial and private customers and its integrity and uninterrupted operation within the acceptable voltage limits and quality standards is critical for various devices on the line. Monitoring and analyzing the line's behavior is critical to the electricity provider/municipality to ensure the required level of service.

Applicant has further realized that millions of networked lighting controls have been deployed in municipal and utility lighting systems around the world. Beyond the ability to turn on and off the streetlights remotely, dim them up or down, schedule long term operations, and get warnings about potential problems, many of the networked lighting controllers being deployed have built in sensors, such as power meters. Lighting system operators are currently using the data collected by the power meters in the networked lighting controls to calculate total energy consumption and even for billing purposes.

Applicant has realized that the street light control network can be utilized to provide distributed and simultaneously synchronized, sophisticated power line monitoring and power quality analysis, thereby turning each networked lighting control unit into an enhanced power line monitor.

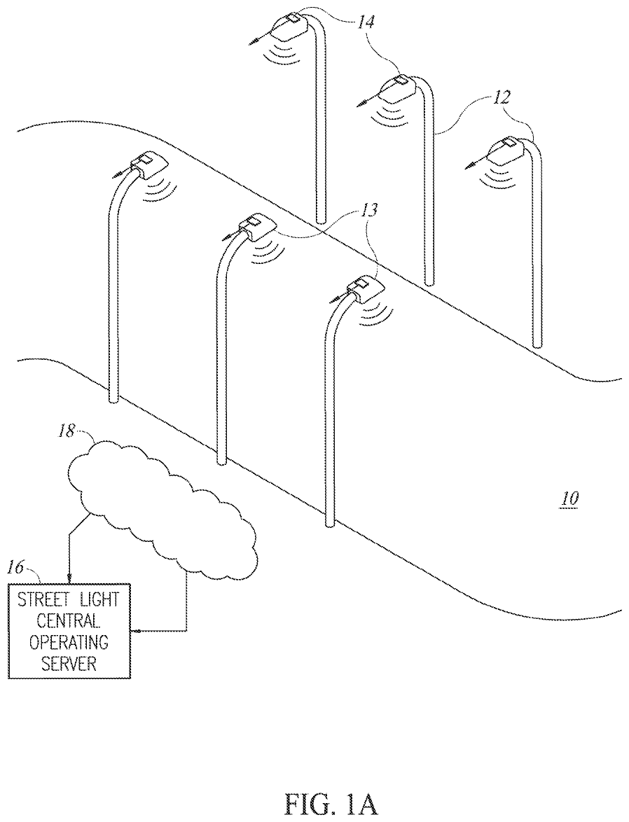

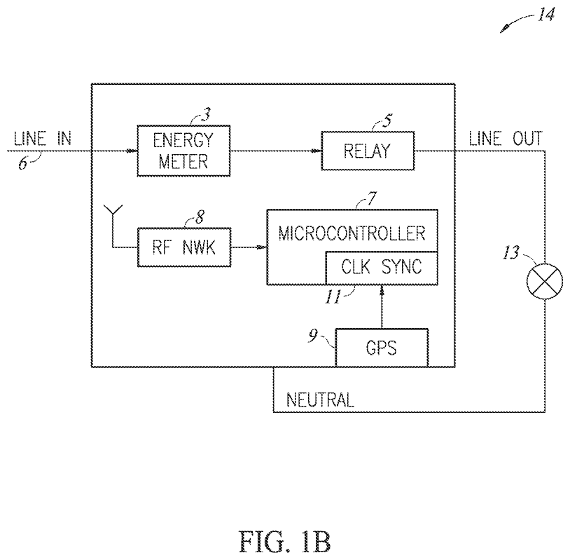

Reference is now made to FIG. 1A, which illustrates a prior art street 10 with multiple street lights 12, each having a luminaire 13 and its associated control unit 14, and to FIG. 1B, which details an exemplary control unit 14. An exemplary street light system may be the T-Light™ Galaxy, PRO or NBIOT units, commercially available from ST Engineering Telematics Wireless Ltd. of Israel.

Each control unit 14 may comprise a built-in electricity meter 3 (FIG. 1B) and a relay 5 which may be connected in series on a power line 6 with luminaire 13. Electricity meter 3 and relay 5 may, together, that, together, control the power which passes through to luminaire 13. Electricity meter 3 may provide its energy readings to a microcontroller 7, such as an MSP430 microcontroller, commercially available from Texas Instruments Incorporated of the USA. Microcontroller 7 may either transmit its data, typically wirelessly via a modem 8, to a city-wide, street light central operating server 16 (FIG. 1A). The transmission may be periodically or upon request. As shown in FIG. 1B, each control unit 14 may also have a built-in GPS (global positioning system) unit 9, which may provide its GPS coordinates to microcontroller 7 at least at installation and/or upon request.

Electricity meter 3 may monitor voltage and current arriving at luminaires 13, and may also monitor power factor and power consumption of luminaires 13. Microcontrollers 7 may provide power consumption and average voltage data of their luminaire 13, during a predetermined period of time, to central operating server 16, which, in turn, may use the data to determine at least total energy consumption.

It will be appreciated that FIG. 1A shows a street light control system having a plurality of nodes (control units 14) connected to central street light operating server 16 over a wireless communication network 18, such as an NLC (networked lighting control) network. The nodes typically are synchronized, such that each system clock 11, forming part of microcontroller 7 of each control unit 14, may have the same time. This may be achieved in many ways. For example, system clock 11 may have an astronomical clock therein. Alternatively, system clock 11 may receive a synchronization clock signal from communication network 18, or, alternatively, may receive a synchronized time-stamp from GPS 9. Each node may transmit the measured, synchronized data to central operating server 16. Server 16 typically may analyze the data received from luminaires 13 and may also have the capability to send commands to each node or to a group of nodes, such as to change their operating parameters.

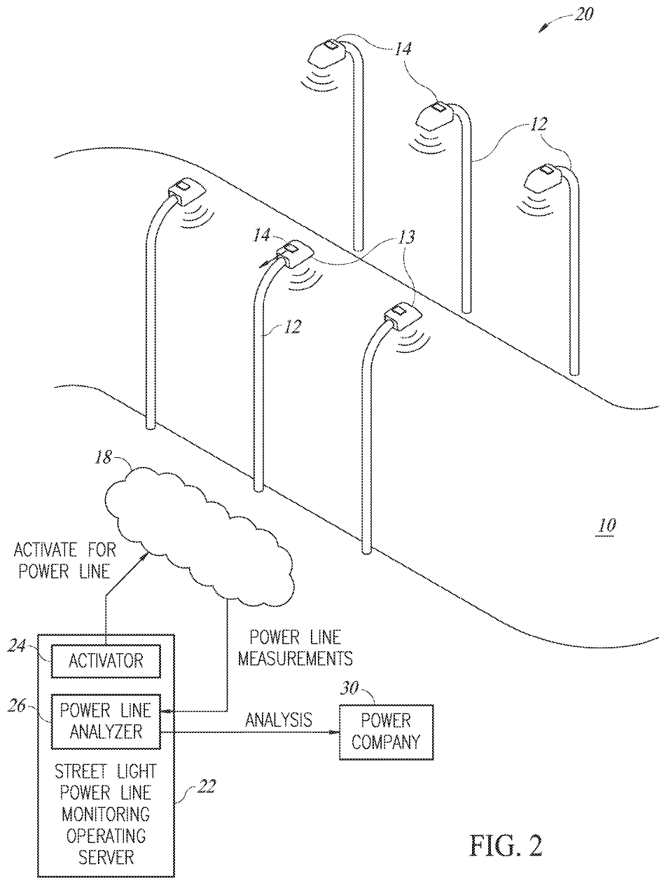

Reference is now made to FIG. 2, which illustrates a street light, power line monitoring (SLPLM) system 20, constructed and operative in accordance with a preferred embodiment of the present invention. SLPLM system 20 comprises a SLPLM operating server 22, similar to server 16 in its control of control units 14 over network 18 and its ability to send and receive data from them, but with the addition of an activator 24 and a power line analyzer 26 to switch a portion of control units 14 to temporary power line monitoring. To do so, SLPLM system 20 may add an additional command to control units 14 to effect the conversion of electricity meters 3 of the relevant portion from power measurement for street light operation to the sensing of various power line parameters. The additional command may simply be a command to change the operating parameters of electricity meters 3, an ability existing electricity meters have.

When SLPLM server 22 may identify a problem with the power line, such as from a user complaint, from a street light operation error, periodically, etc., SLPLM server 22 may determine the location of the problem. This may involve requesting GPS data from the control unit 14 of the street light 12 which failed, or from map or GPS data generated in response to the user complaint.

With the location of the problem defined, activator 24 may determine which street light control units 14 may be in the general vicinity of the problem, typically by comparing their built in GPS location data with the problem location and selecting those within a predefined range from the problem location. Alternatively, activator 24 may review a database of control units 14 to find those which are on the same street or in the same neighborhood to the power line at the problem location (e.g. the “problem power line”), or which are connected to the problem power line or which are connected to one of the power lines running through a street light cabinet to which the problem power line is also connected.Activator 24 may then command, via network 18, control units 14 of the selected street lights 12 to change the operating parameters of their electricity meters 3 to power line monitor operation for a predefined monitoring duration. Exemplary changes may include changing from the street light mode of measuring periodically, such as once an hour, to measuring continuously for a predefined duration, such as for 24 hours.

Since, with increased duration, electricity meters 3 may produce a lot of data extremely fast and since network 18, like most NLC networks, is typically a narrow band network, it may be difficult to transmit the raw data to be analyzed by power line analyzer 26 in real-time. Therefore, activator 24 may also instruct the selected control units 14 to generate the electrical parameters of the maximum, and/or minimum values of any of the signals and, to further reduce the amount of data, to also compare such values to reference values and to transmit only those values which exceed the reference values in one direction or the other. Such a monitoring may happen over a predefined period of time, as relevant to the problem and as commanded by activator 24.

The selected control units 14 may transmit their power line monitoring data over network 18 to SLPLM server 22 at any appropriate rate and as instructed by activator 24. The power line monitoring data may be time-stamped since, as described hereinabove, control units 14 may be synchronized as part of the operation of network 18. This may provide a synchronized picture of the location of the power line failure.

Moreover, activator 24 may adjust the monitoring rate and duration as necessary, either based on the suspected problem or based on an analysis generated by power line analyzer 26, as described hereinbelow.

Power line analyzer 26 may analyze the data received from the designated groups of luminaires 13 to find and evaluate any anomalies on the relevant power lines (e.g. voltage or current “spikes”, their value, duration, repetition rate, etc.). For example, analyzer 26 may map the problems, both over time and in space. Analyzer 26 may generate a histogram over time, showing how many times or for how long the data is above a given threshold and/or showing where such anomalies occurred.

Analyzer 26 may issue reports and alerts to a power supplier/authority 30 about the power line anomalies and its nature. Power line analyzer 26 may utilize any suitable software analytic tool, such as the Oracle Analytics Cloud platform, commercially available from Oracle Corporation of the USA, to find such anomalies. Alternatively, power line analyzer 26 may utilize deep learning techniques and AI (artificial intelligence) to analyze the received data.

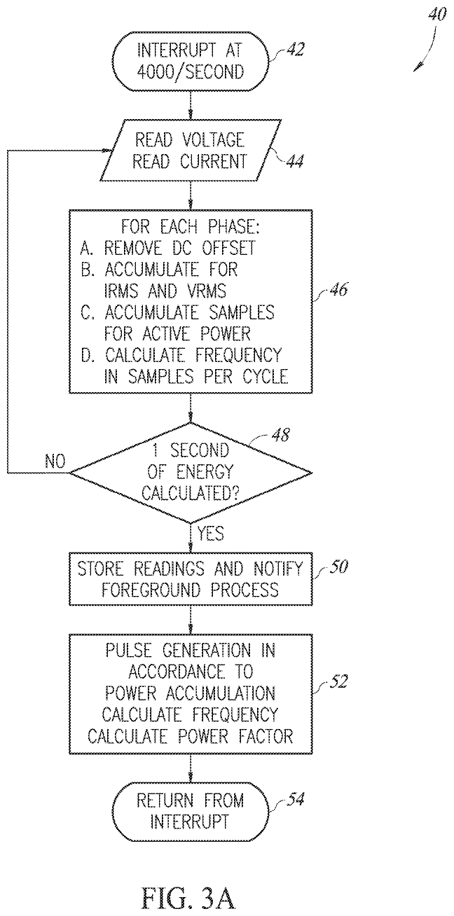

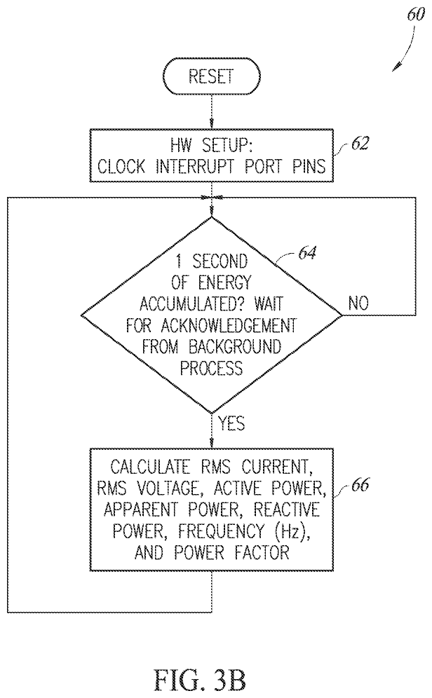

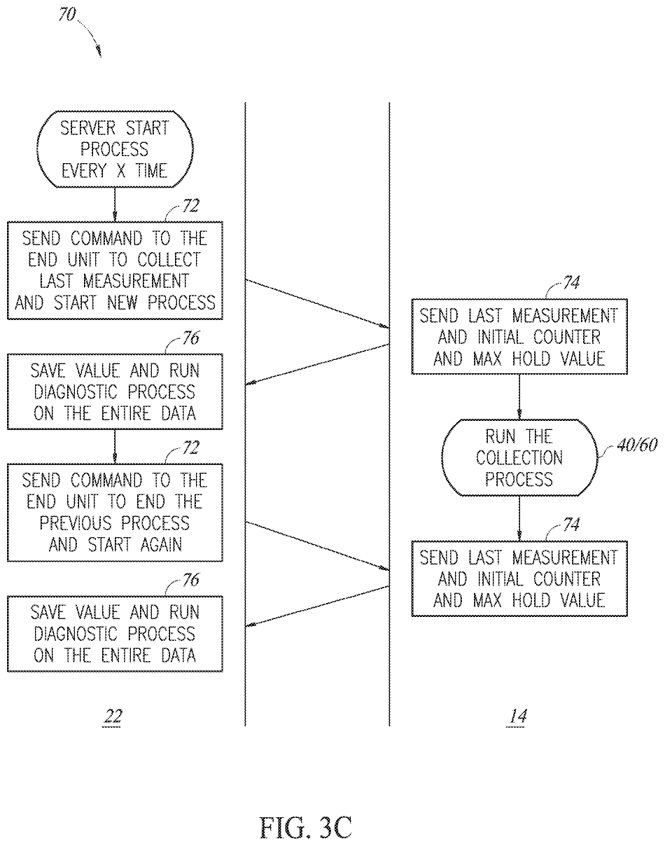

Reference is now made to FIGS. 3A, 3B and 3C, which illustrate the operation of microcontroller 7 in street light mode. FIG. 3A illustrates a background process 40, FIG. 3B illustrates a foreground process 60, and FIG. 3C illustrates a server process 70 interacting with control unit 14.

In street light mode, background process 40 may use one of its interrupts as a trigger (step 42) to collect (step 44) voltage and current samples, such as at 4000 samples/second. Background process 40 may process (step 46) the samples separately for each phase. This may involve removing any DC (direct current) offset and accumulating the voltage and current samples, which may be 16-bit and 24-bit samples, respectively, in 64-bit registers, for a later RMS (root-mean-squared) calculation. This step may also involve accumulating active power samples also in 64-bit registers, and calculating the frequency of the power signal, in samples/cycle.

Background process 40 may repeat the sampling and processing process for one second, as checked by step 48, after which, it may store (step 50) the resultant data and may send a notification to the foreground process of FIG. 3B. Finally, background process 40 may determine (step 52) an energy proportional pulse size as a function of the power accumulation, may finalize the calculation of the frequency of the power signal in samples/cycle and may determine current lead and lag conditions, to determine a “power factor” value.

Foreground process 60 may handle (step 62) the initial setup of the hardware and software of microcontroller 7, such as at manufacture and after a reset. This may include the clock, the interrupts and the port pins as well as any software initialization.

In step 64, foreground process 60 may wait for a notification from background process 40 that it has finished accumulating the energy data. Upon receipt of the notification, foreground process 60 may access the accumulation registers to calculate (step 64) the root-mean-square values IRMS and VRMS of the current and voltage, respectively. Foreground process 60 may also calculate the active power Pactive, the apparent power Papparent, the reactive power Preactive, the frequency in Hertz, and the power factor PF, typically using standard calculations, such as:

$$\begin{matrix}Pactive = PGAIN * \frac{1}{N} {\sum }_{i = 1}^{N} {Vsamp}^{( i )} * {Isamp}^{( i )} & ( Equation 1 ) \\ Preactive = PGAIN * \frac{1}{N} {\sum }_{i = 1}^{N} Vsamp , 9 {0}^{( i )} * {Isamp}^{( i )} & ( Equation 2 ) \\ Papparent = Vrms * Irms & ( Equation 3 ) \\ PF = cos φ \frac{Pactive}{Papparent} & ( Equation 4 )\end{matrix}$$

where N is the number of samples of the accumulated energy data, Vsamp⁽ⁱ⁾ is a voltage sample at a sample instant i, Vsamp, 90⁽ⁱ⁾ is a voltage sample at sample instant i, shifted by 90 degrees, Isamp⁽ⁱ⁾ is a current sample at sample instant i, PGAIN is a known scaling factor for active or reactive power and φ is the angle between voltage and the current.

Foreground process 60 may continually repeat steps 64 and 66 and, as detailed in FIG. 3C, may transmit its calculated data when requested by SLPLM server 22, or at predefined times.

FIG. 3C is a timing diagram showing how a server process 70 interacts with control unit 14 to receive the data generated by foreground process 60. In step 72, server process 70 may instruct each control unit 14 to transmit the last measurement over network 18 and then to start a new collection process, comprising both background process 40 and foreground process 60. In response, each control unit 14 may send (step 74) its last set of measurement data to SLPLM server 22 and then may initialize its counter and max hold value. Server process 70 may receive (step 76) the data, save it and then may run a diagnostic process on the entire set of measurement data from all control units 14.

Server process 70 may repeat periodically, such as every X seconds, where X is typically one hour. However, when there is a failure of power line 6, server process 70 may act as activator 24 and may instruct control unit 14 to run in the power line mode.

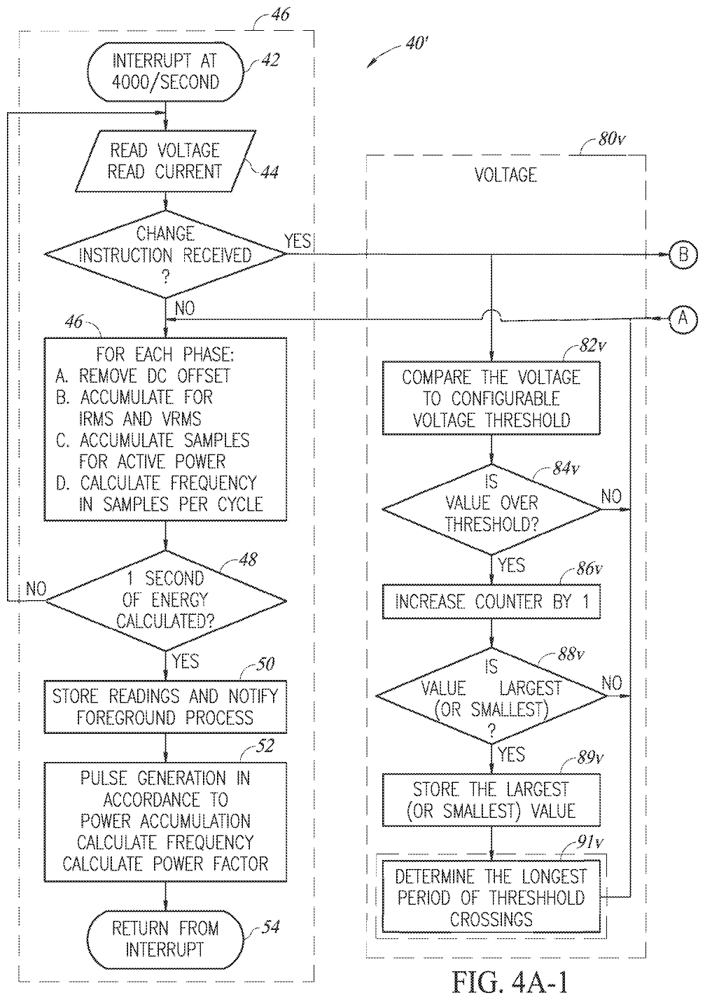

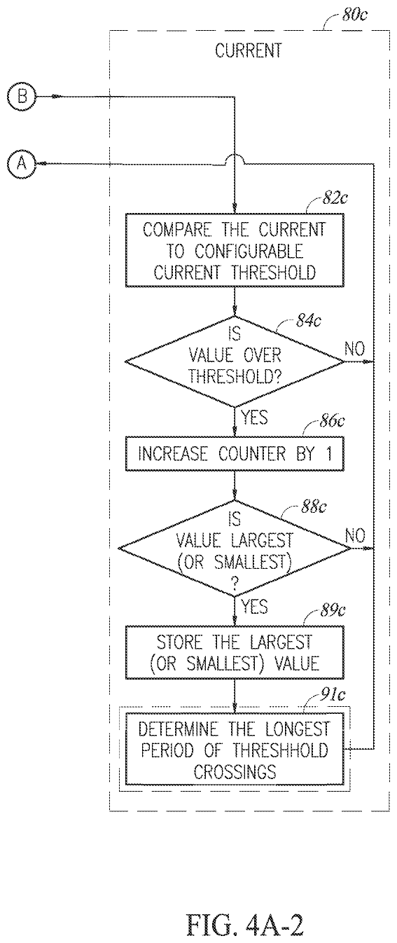

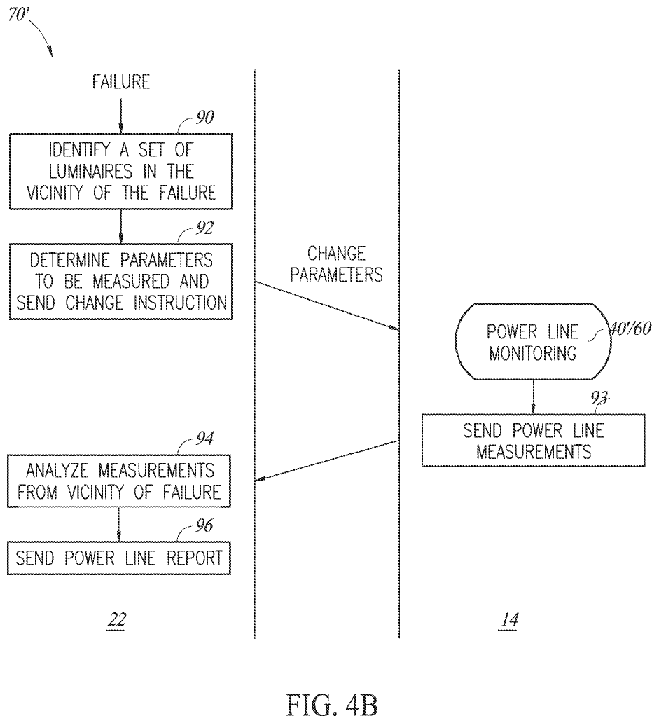

Reference is now made to FIGS. 4A-1 and 4A-2, which illustrate the background process, here labeled 40′, which microcontroller 7 may implement during its power line monitoring mode, and to FIG. 4B, which illustrates the server process, here labeled 70′, which SLPLM server 22 may implement for power line monitoring.

Monitoring mode background process 40′ (FIGS. 4A-1 and 4A-2) may include street light mode background process 40 as well as one or both of a voltage comparison process 80v and a current comparison process 80c, both comparing their received values with their configurable threshold value and comparing their received values with others to find a largest and/or smallest value.

Monitoring mode background process 40′ may begin as street light mode process 40 by reading the voltage and current values (step 44) after the process is triggered (step 42). If a parameter change instruction has been received (as checked in step 45), background process 40′ may provide the received voltage value to voltage comparison process 80v and the received current value to current comparison process 80c. Both comparison processes implement the same steps on their received value, where each step is labeled ‘v’ in voltage comparison process 80v and ‘c’ in current comparison process 80c.

Comparison processes 80v and 80c may compare (steps 82v, 82c) the received voltage and current, respectively, to their configurable thresholds. Each comparison process 80v or 80c may continue to steps 86v or 86c, respectively, only if the received voltage or current is above the threshold, as checked by steps 84v and 84c, respectively. Otherwise, comparison processes 80v or 80c may continue to step 46 of street light background process 40.

However, if the received voltage or current is above the threshold, the relevant comparison process 80v or 80c may increase (step 86v or 86c) an overvoltage counter by 1 and may then check, in step 88v or 88c, if the received value is the largest or smallest value yet received in this sampling period. If it is, the relevant comparison process 80v or 80c may store it (in step 89v or 89c) as the largest or smallest value so far.

It will be appreciated that the relevant comparison process 80v or 80c may not only count the total number of times that the measurement crossed the threshold within a period of time, it may also optionally determine (step 91v or 91c) if the threshold crossing continued for more than one sample and, if so, what was the longest period of threshold crossings. To do so, it may count the maximum number of times within that period that the threshold crossing continued. Measuring the length of threshold crossing provides a better understanding of the failure.

At this point, comparison processes 80v or 80c may continue to step 46 of street light background process 40. Street light background process 40 may continue through steps 46-54, where the threshold counter and largest and smallest values may be made available to foreground process 60 for transmission to SLPLM server 22.

FIG. 4B shows server process 70′, which server 22 may implement when it receives an indication of a power line failure of some kind. Server process 70′ may begin, in step 90, as activator 24 and may identify a set of luminaires in the vicinity of the problematic power line, as discussed hereinabove. Server process 70′ may then determine (step 92) which power line parameters to measure and may instruct the control units 14 of the identified luminaires 13 to change their parameters accordingly.

Each control unit 14 may then change its parameters to implement power line monitoring, using power line background process 40′ and foreground process 60. Each control unit 14 may transmit (step 93) its data, continually, periodically or as requested, to server 22 which may then analyze (step 94) the measurements it receives (acting as analyzer 26). Finally, server process 70′ may generate and send (step 96) its power line report.

The following is an example of the operation of SLPLM system 20. In this example, the municipality may have installed equipment, such as a camera or an IoT (internet of things) sensor, on the lamp pole of a street light and may have connected the equipment to the power provided by the pole. The municipality may determine that the equipment has malfunctioned and may want to investigate the cause of the malfunction. In this example, the regular monitoring of the power consumption and averaged voltage performed by control units 14 of the luminaire 13 of the lamp pole does not provide adequate information regarding the possible cause of malfunction. Therefore, the user at the municipality may notify activator 24 of the location of the malfunction. Activator 24 may determine a general vicinity of the failed equipment, may determine which control units 14 may be in that vicinity and may then transmit a ‘change to power monitor’ command to the selected control units 14. This may activate power line background process 40′.

Accordingly, the selected control units 14 may change the line measurement parameters of their electricity meters 3 from monitoring the average voltage to measuring the peak voltage and peak current (from the determined largest and smallest values) during the defined period of time, as synchronized among the converted control units 14.

It will be appreciated that control units 14 may measure the power line parameters at a very high rate, compared to standard power line measurements, without any change to the operating rate of control units 14. That is because, in order to provide quality power line measurements, control units 14 already measure the power line at a very high rate, such as 4000 samples/sec, during street light operation. Thus, with very little change, SLPLM system 20 may provide power line monitoring at a very high sampling rate.

Each converted control unit 14 may transmit its data over network 18 to power line analyzer 26 which, in turn, may create a power line behavior picture for the converted set of control units 14. The picture may include peaks and fast transients in voltage and current and its distribution along the power line over time and location. Power line analyzer 26 may also review the behavior picture to determine the nature of the anomaly in the power line.

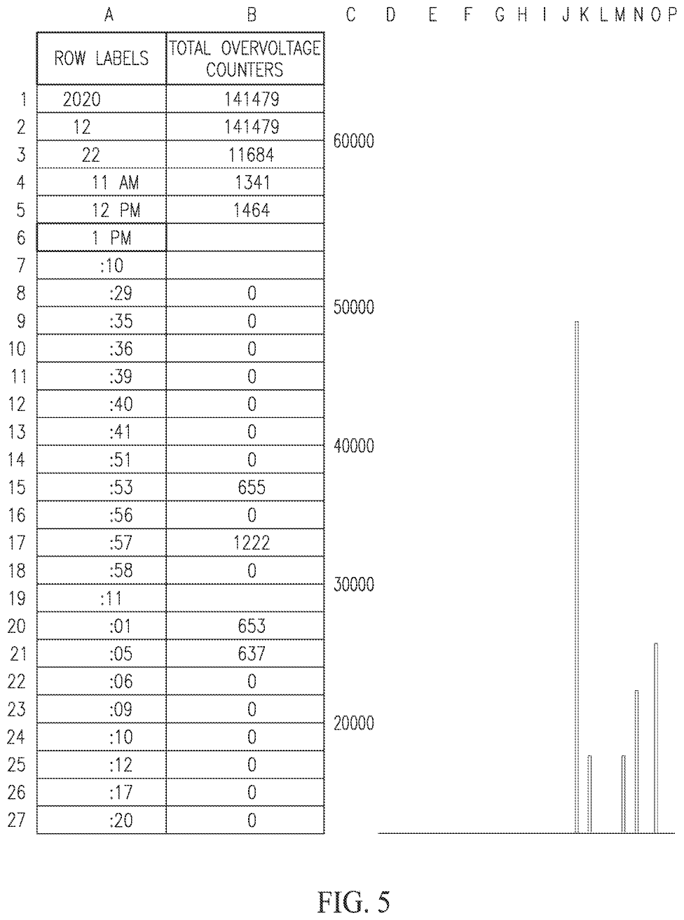

An exemplary power line behavior picture is shown in FIG. 5, to which reference is now made. FIG. 5 is both a listing and a histogram of the number of overvoltage counters per hour of the day for one power line, with the minutes of 1 pm being shown in detail. As can be seen, there were 11684 overvoltage events on the 22^{nd}, of which 1464 happened during the hour of 12 pm, 655 happened at 1:10:53 pm and 1222 happened at 1:10:57 pm with no other events happening during the minute of 1:10 pm. This picture may show power company 30 the failure and may enable it to determine the cause of the failure. It will be appreciated that such an exact picture is only possible because the clocks of control units 14 are synchronized, making it possible to generate a synchronized snap shot of where and when failure events are happening. Moreover, the type of behavior picture shown in FIG. 5 is exemplary only; other types of power line behavior pictures may be generated and are included in the present invention.

As a result, power line analyzer 26 may inform the municipality or power company 30 about the type and location of the problem to facilitate its resolution. Alternatively, power line analyzer 26 may generate the power line picture and may provide it to the municipality or power company 30 for their internal analysis.

SLPLM system 20 may detect other types of power line failures, such as any of the following:

Potential grounding and safety hazards to local power networks;

Phase imbalance on the power line caused by bad grounding and non-symmetrical loading;

The existence of aging contactors and loose electrical connections within the power line grid, and their location within the grid;

Local power consumption anomalies, such as voltage drops, and their locations within the grid due to abnormal or illegal connections to the grid;

The integrity of the power line;

Local change of power factor which affects utility revenues; and

Location of bad weather hazards to the power lines and the resultant intermittent outages caused by high winds or falling branches.

It will be appreciated that SLPLM system 20 may utilize an existing street light monitoring system to identify power line anomalies using unique operational procedures, data collection and data analysis. The SLPLM system 20 may identify the problem with any particular power line as well as the location of the problem. Importantly, SLPLM system 20 may activate a set of power line monitors only in the area of an identified problem and may activate them to monitor specific electrical parameters not associated with its “normal” operation for street light operation.

The SLPLM system 20 may provide a powerful, synchronized “snap shot” of the operation of the power grid at multiple locations, providing a much more accurate measurement of the electrical distribution grid than currently available to power companies. This may improve overall performance of the power companies.

It will be appreciated that SLPLM system 20 may utilize enhanced data collection and distributed intelligence to provide a clear view of power quality, potential problems on the grid, as well as more accurate details on the functioning of the lights themselves.

It will further be appreciated that activator 24 may alternatively be implemented in each control unit 14. In this embodiment, each control unit 14 may determine if it measured a failure of some kind and, if so, may instruct its neighbors to switch to power line monitoring.

Unless specifically stated otherwise, as apparent from the preceding discussions, it is appreciated that, throughout the specification, discussions utilizing terms such as “processing,” “computing,” “calculating,” “determining,” or the like, refer to the action and/or processes of a general purpose computer of any type, such as a microcontroller, a server, mobile computing devices, smart appliances, cloud computing units or similar electronic computing devices that manipulate and/or transform data within the computing system's registers and/or memories into other data within the computing system's memories, registers or other such information storage, transmission or display devices.

Embodiments of the present invention may include apparatus for performing the operations herein. This apparatus may be specially constructed for the desired purposes, or it may comprise a computing device or system typically having at least one processor and at least one memory, selectively activated or reconfigured by a computer program stored in the computer. The resultant apparatus when instructed by software may turn the general purpose computer into inventive elements as discussed herein. The instructions may define the inventive device in operation with the computer platform for which it is desired. Such a computer program may be stored in a computer readable storage medium, such as, but not limited to, any type of disk, including optical disks, magnetic-optical disks, read-only memories (ROMs), volatile and non-volatile memories, random access memories (RAMs), electrically programmable read-only memories (EPROMs), electrically erasable and programmable read only memories (EEPROMs), magnetic or optical cards, Flash memory, disk-on-key or any other type of media suitable for storing electronic instructions and capable of being coupled to a computer system bus. The computer readable storage medium may also be implemented in cloud storage.

Some general purpose computers may comprise at least one communication element to enable communication with a data network and/or a mobile communications network.

The processes and displays presented herein are not inherently related to any particular computer or other apparatus. Various general-purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A street light control system, the street light control system comprising a plurality of street lights connected to an electrical distribution grid of power lines, a communication network, and a street light central control server, each street light comprising a luminaire and a control unit comprising an electricity meter, the system comprising:
an activator to identify a set of luminaires in a vicinity of a power line problem and to instruct them to switch from a street light mode to a power line monitoring mode in which operating parameters of their electricity meters are changed so as to act as power line monitors; and
a power line analyzer to receive data via said communication network from said power line monitors and to create a power line behavior picture.

2. The system of claim 1, wherein said power line behavior picture is a synchronized snap shot of power distribution in said vicinity.

3. The system of claim 1, wherein said power line behavior picture is a measured picture of a portion of an electrical distribution grid.

4. The system of claim 1, wherein said operating parameters are changed from monitoring, during said street light mode, an average voltage to measuring, during said power line monitoring mode, at least extreme voltage and extreme current values over a defined period of time.

5. The system of claim 4 and wherein at least one control unit of said street lights comprises a unit to determine said average voltage and/or current of its said street light, during said street light mode, from voltages and/or currents sampled at a high rate and wherein said high rate of sampling is used during said power line monitoring mode for said measuring at least said extreme voltage and said extreme current values.

6. The system of claim 1 and wherein each said control unit comprises a synchronized clock, synchronized at least to clocks in other control units, and wherein said data is time-stamped by said synchronized clock.

7. The system of claim 6 and wherein said synchronized clock receives a time-stamp signal from one of: a synchronization clock of said communication network, an astronomical clock, and a time-stamp portion of a GPS (global positioning system) unit.

8. The system of claim 1, wherein said operating parameters are length of time for sampling and type of measurement.

9. The system of claim 1, wherein said activator is implemented in said street light central control server.

10. The system of claim 1, wherein said activator is implemented in said control unit.

11. A method for providing a power line behavior picture, the method comprising:
having a plurality of street lights connected to an electrical distribution grid of power lines, a communication network, and a street light central control server, each street light comprising a luminaire and a control unit comprising an electricity meter;
identifying a set of luminaires in a vicinity of a power line problem;
instructing said identified luminaires to switch from a street light mode to a power line monitoring mode in which operating parameters of their electricity meters are changed so as to act as power line monitors;
receiving data via said communication network from said power line monitors; and
creating said power line behavior picture from said data.

12. The method of claim 11, wherein said power line behavior picture is a synchronized snap shot of power distribution in said vicinity.

13. The method of claim 11, wherein said power line behavior picture is a measured picture of a portion of an electrical distribution grid.

14. The method of claim 11, and comprising changing said operating parameters from monitoring, during said street light mode, an average voltage to measuring, during said power line monitoring mode, at least extreme voltage and extreme current values over a defined period of time.

15. The method of claim 14 and comprising determining said average voltage and/or current of each identified luminaire, during said street light mode, from voltages and/or currents sampled at a high rate and using said high rate of sampling during said power line monitoring mode for said measuring at least said extreme voltage and said extreme current values.

16. The method of claim 11 and comprising time-stamping said data by a synchronized clock forming part of each said control unit.

17. The method of claim 16 and comprising receiving a time-stamp signal from one of: a synchronization clock of said communication network, an astronomical clock, and a time-stamp portion of a GPS unit.

18. The method of claim 11, wherein said operating parameters are length of time for sampling and type of measurement.

19. The method of claim 11, wherein said identifying and instructing are provided by said street light central control server.

20. The method of claim 11, wherein said identifying and instructing are provided by said control unit.
